(19) United States
(12) Patent Application Publication
(10) Pub. No.: US 2024/0054074 A1
(43) Pub. Date: Feb. 15, 2024

(54) COMPUTER-READABLE RECORDING MEDIUM STORING INFORMATION PROCESSING PROGRAM, INFORMATION PROCESSING METHOD, AND INFORMATION PROCESSING DEVICE

(71) Applicant: Fujitsu Limited, Kawasaki-shi (JP)

(72) Inventor: Masaki ARAI, Kawasaki (JP)

(73) Assignee: Fujitsu Limited, Kawasaki-shi (JP)

(21) Appl. No.: 18/311,260

(22) Filed: May 3, 2023

(30) Foreign Application Priority Data
Aug. 9, 2022 (JP) 2022-127302

(51) Int. Cl. G06F 12/0802

(52) U.S. Cl. CPC G06F 12/0802; G06F 2212/6042

(57) ABSTRACT

A non-transitory computer-readable recording medium stores an information processing program for causing a computer to execute processing including: classifying a plurality of calculation nodes each in charge of arithmetic processing regarding to an access destination according to an identifier of an own node by using a cache into a plurality of groups, based on a remainder obtained by dividing a value that corresponds to the access destination by the number of sets in the cache; and acquiring profile information of the cache, that corresponds to any one group, by performing a simulation that imitates an access to the cache in the arithmetic processing, for at least any one of the calculation nodes classified into any one group, for any one of the plurality of groups.

### CROSS-REFERENCE TO RELATED APPLICATION

This application is based upon and claims the benefit of priority of the prior Japanese Patent Application No. 2022-127302, filed on Aug. 9, 2022, the entire contents of which are incorporated herein by reference.

### FIELD

The embodiment discussed herein is related to an information processing program, an information processing method, and an information processing device.

### BACKGROUND

Typically, it is desirable to acquire profile information of a cache for a large-scale high performance computing (HPC) application that is distributed by a plurality of cores and detect a core with a relatively large number of cache misses based on the profile information. Here, there is a technique for relatively easily acquiring the profile information of the cache by rewriting an application into a program used to acquire the profile information of the cache and executing the rewritten program.

Japanese Laid-open Patent Publication No. 2014-232369, Japanese Laid-open Patent Publication No. 8-263372, Japanese Laid-open Patent Publication No. 2000-215104, U.S. Patent Application Publication No. 2020/0210334, and U.S. Pat. No. 6,952,664 are disclosed as related art.

### SUMMARY

According to an aspect of the embodiments, a non-transitory computer-readable recording medium stores an information processing program for causing a computer to execute processing including: classifying a plurality of calculation nodes each in charge of arithmetic processing regarding to an access destination according to an identifier of an own node by using a cache into a plurality of groups, based on a remainder obtained by dividing a value that corresponds to the access destination by the number of sets in the cache; and acquiring profile information of the cache, that corresponds to any one group, by performing a simulation that imitates an access to the cache in the arithmetic processing, for at least any one of the calculation nodes classified into any one group, for any one of the plurality of groups.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is an explanatory diagram illustrating an example of an information processing method according to an embodiment;

FIG. 2 is an explanatory diagram illustrating an example of an information processing system 200;

FIG. 3 is a block diagram illustrating a hardware configuration example of an information processing device 100;

FIG. 4 is a block diagram illustrating a functional configuration example of the information processing device 100;

FIG. 5 is an explanatory diagram illustrating an operation example of the information processing device 100;

FIG. 6 is an explanatory diagram illustrating an example of content of program information 501;

FIG. 7 is an explanatory diagram illustrating an example of content of program data information 502;

FIG. 8 is an explanatory diagram illustrating an example of content of variable data information 503;

FIG. 9 is an explanatory diagram illustrating an example of content of cache configuration information 504;

FIG. 10 is an explanatory diagram illustrating an example of content of calculation node information 505;

FIG. 11 is an explanatory diagram illustrating an example of components;

FIG. 12 is an explanatory diagram illustrating an example of calculation node group information 512;

FIG. 13 is an explanatory diagram (part 1) illustrating an example of a profile information generation program 511;

FIG. 14 is an explanatory diagram (part 2) illustrating an example of the profile information generation program 511;

FIG. 15 is a flowchart illustrating an example of an overall processing procedure; and

FIG. 16 is a flowchart illustrating an example of a generation processing procedure.

### DESCRIPTION OF EMBODIMENTS

There is related art, for example, that counts up a miss variable by one in a case where tag information corresponding to a byte address of an array X is not stored in a storage unit. Furthermore, for example, there is a technique for simulating a cache memory, detecting when a transferred data address is not within an address range of data that is assumed to be captured into the cache memory, as a cache miss, and counting up the number of accesses and the number of cache misses. Furthermore, for example, there is a technique for counting the number of times of hits on an address registered in an entry of a TAG address array. Furthermore, for example, there is a technique for determining a cache hit ratio of an address of which a sample is extracted. Furthermore, for example, there is a technique for simulating a performance of a cache.

However, with the related art, there is a case where it is difficult to detect a core with a relatively large number of cache misses, from among a plurality of cores. For example, as the number of cores increases, a processing load caused when the profile information of the cache is acquired tends to be enormous, and it is difficult to detect the core with the relatively large number of cache misses from among the plurality of cores.

In one aspect, an object of the embodiment is to make it easier to detect a specific calculation node.

Hereinafter, an embodiment of an information processing program, an information processing method, and an information processing device according to the present disclosure will be described in detail with reference to the drawings. The embodiment is an embodiment that relates to an architecture for improving efficiency of data transfer.

(Example of Information Processing Method According to Embodiment)

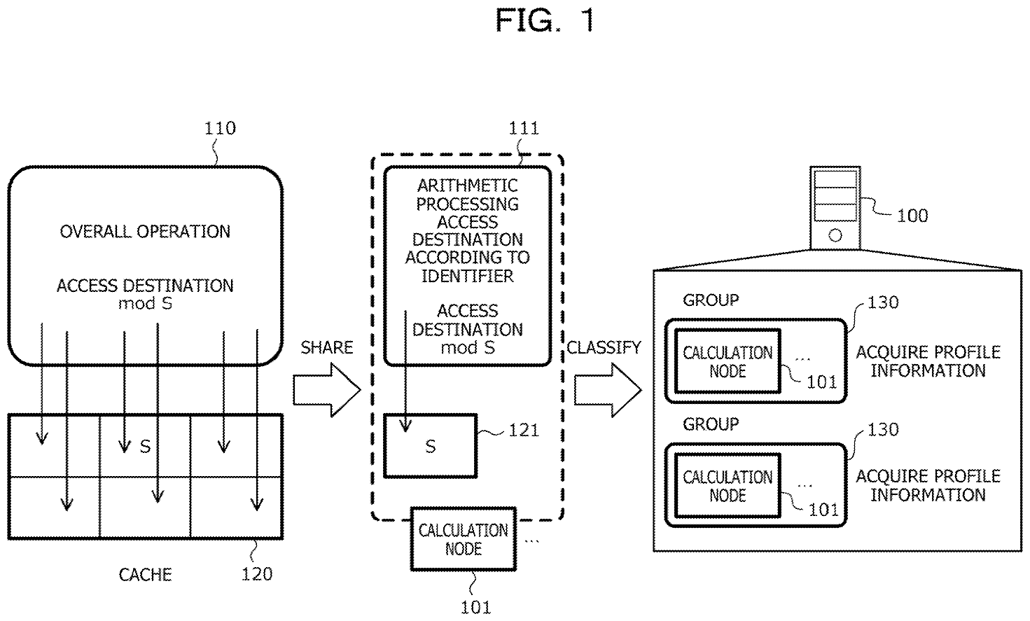

FIG. 1 is an explanatory diagram illustrating an example of an information processing method according to an embodiment. An information processing device 100 is a computer that acquires profile information of a cache in predetermined arithmetic processing. The information processing device 100 is, for example, a server, a personal computer (PC), or the like.

The predetermined arithmetic processing is arithmetic processing, for example, corresponding to a large-scale HPC application. For example, the predetermined arithmetic processing is formed of a floating point operation for operating an array and loop processing. For example, the predetermined arithmetic processing may have a property such that a use efficiency of the cache in the arithmetic processing easily affects a performance regarding a specific function implemented by the arithmetic processing. The predetermined arithmetic processing may be distributed by a plurality of calculation nodes, for example. The profile information includes, for example, information regarding a cache hit and a cache miss, for each set in a cache. The set is a unit of a storage area in a cache.

For example, in order to analyze an access trend to a cache, it is desirable to acquire the profile information of the cache. For example, it is desirable to acquire the profile information of the cache in order to detect the calculation node with a relatively large number of cache misses, from among the plurality of calculation nodes that analyzes the access trend to the cache and distributes the predetermined arithmetic processing.

Typically, a method for acquiring the profile information of the cache by executing the large-scale HPC application is considered. For example, by executing the large-scale HPC application with an actual machine and using a function of a central processing unit (CPU) of the actual machine, the profile information of the cache is acquired. However, this method has a problem in that it is difficult to acquire the profile information of the cache.

For example, there is a problem that a time required when the large-scale HPC application is executed easily becomes enormous and a time required when the profile information of the cache is acquired easily becomes enormous. For example, when the large-scale HPC application is executed, an actual machine is used. Therefore, there is a problem in that a cost required for acquiring the profile information of the cache tends to increase. The cost is, for example, a usage fee of the actual machine, power consumption of the actual machine, or the like. For example, it is difficult to acquire the profile information that enables to analyze the access trend to the cache in detail, even if the functions of the CPU are used.

On the other hand, a method is considered for rewriting an application into a program used to acquire the profile information of the cache and executing the rewritten program so as to relatively easily acquire the profile information of the cache. For this method, for example, Japanese Laid-open Patent Publication No. 2014-232369 described above can be referred.

However, even with this method, there is a case where it is difficult to efficiently acquire the profile information of the cache and detect the calculation node with the relatively large number of cache misses, from among the plurality of calculation nodes. For example, as the number of calculation nodes increases, the processing load caused when the profile information of the cache is acquired tends to be enormous, and it is difficult to detect the calculation node with the relatively large number of cache misses, from among the plurality of calculation nodes.

Therefore, in the present embodiment, an information processing method will be described that can easily analyze an access trend to a cache and easily detect a specific calculation node such as a calculation node with a relatively large number of cache misses, from among a plurality of calculation nodes.

In FIG. 1, it is assumed that an overall operation 110 exist. It is assumed that a cache 120 used for the overall operation 110 exist. The cache 120 includes a plurality of sets 121. The set 121 is a section obtained by dividing the cache 120, and is a unit of a storage area in the cache 120.

The overall operation 110 includes a plurality of pieces of arithmetic processing respectively for different access destinations. The overall operation 110 executes the arithmetic processing about the access destination, using any one of the sets 121 in the cache 120, according to a remainder obtained by dividing a value indicating the access destination by the number S of sets in the cache 120, for example. The access destination is, for example, expressed by an address. The value indicating the access destination is, for example, a value obtained by dividing the address by a size of a block.

It is assumed that the overall operation 110 can be distributed by a plurality of calculation nodes 101, for example. For example, in the overall operation 110, arithmetic processing 111 regarding an access destination according to an identifier of a calculation node 101 is in charge of the calculation node 101. It is assumed that the overall operation 110 include the plurality of pieces of arithmetic processing 111.

The calculation node 101 executes the arithmetic processing 111 on the access destination according to the identifier of the own calculation node 101, using the cache 120. For example, the calculation node 101 executes the arithmetic processing 111, by selectively using any one set 121 in the cache 120, according to a remainder obtained by dividing the value indicating the access destination according to the identifier of the own calculation node 101 by the number S of sets in the cache 120.

(1-1) The information processing device 100 classifies the plurality of calculation nodes 101 into a plurality of groups, based on a remainder obtained by dividing a value indicating an access destination by the number of sets in a cache. The access destination is determined according to an identifier of the calculation node 101. The value indicating the access destination is a value obtained by dividing an address of the access destination by a block size in the cache 120, for example.

For example, the information processing device 100 classifies the plurality of calculation nodes 101 into the plurality of groups, so that two or more different calculation nodes 101 having the same remainder value are classified into the same group. As described above, which set 121 in the cache 120 the calculation node 101 uses is different depending on the remainder. Therefore, the information processing device 100 can group the calculation nodes 101 having the same or similar access trends to the cache 120, based on the remainder.

(1-2) The information processing device 100 acquires profile information of a cache, for at least any one of a plurality of groups 130. The information processing device 100 selects, for example, at least any one of the plurality of groups 130. For example, the information processing device 100 may select two or more groups 130.

For example, the information processing device 100 performs a simulation for imitating an access to a cache in arithmetic processing, for at least any one of the calculation nodes 101 classified into any one of the selected groups 130. For example, about the simulation, Japanese Laid-open Patent Publication No. 2014-232369 described above can be referred. For example, the information processing device 100 acquires profile information of a cache corresponding to any one of the selected groups 130, by performing the simulation.

As a result, the information processing device 100 can acquire the profile information of the cache common to the one or more calculation nodes 101 classified into the group 130. Since it is sufficient for the information processing device 100 to acquire the profile information of the cache once for each group 130, a processing load can be reduced, and the profile information of the cache can be efficiently acquired. The information processing device 100 can efficiently detect the calculation node 101 with the relatively large number of cache misses, from among the plurality of calculation nodes 101.

Here, a case has been described where the information processing device 100 acquires the profile information of the cache for at least any one of the plurality of groups 130. However, the embodiment is not limited to this. For example, the information processing device 100 may acquire the profile information of the cache for each of the plurality of groups 130.

Here, a case has been described where the information processing device 100 operates alone. However, the embodiment is not limited to this. For example, the information processing device 100 may cooperate with another computer. For example, there may be a case where a plurality of computers cooperates to implement a function as the information processing device 100. For example, the function as the information processing device 100 may be implemented on the cloud.

(One Example of Information Processing System 200)

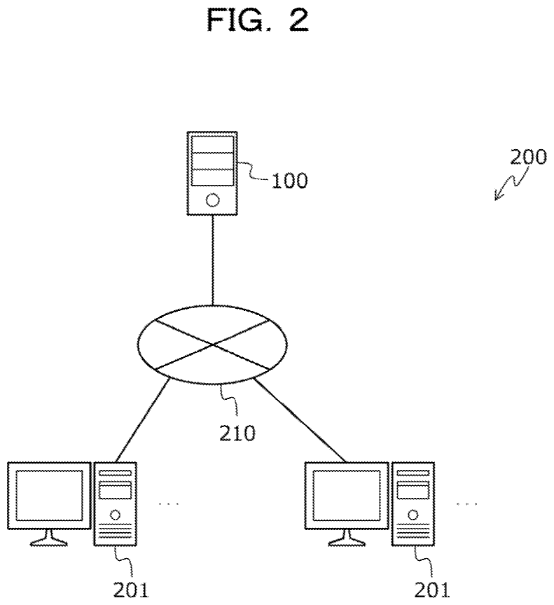

Next, an example of an information processing system 200 to which the information processing device 100 illustrated in FIG. 1 is applied will be described with reference to FIG. 2.

FIG. 2 is an explanatory diagram illustrating an example of the information processing system 200. In FIG. 2, the information processing system 200 includes the information processing device 100 and a client device 201.

In the information processing system 200, the information processing device 100 and the client device 201 are coupled via a wired or wireless network 210. The network 210 is, for example, a local area network (LAN), a wide area network (WAN), the Internet, or the like.

The information processing device 100 is a computer used by a service administrator. The information processing device 100 acquires a processing request. The processing request may indicate, for example, content of predetermined arithmetic processing. The processing request may indicate, for example, the number of sets in a cache used for the predetermined arithmetic processing. The processing request may indicate, for example, the number of calculation nodes that distribute the predetermined arithmetic processing. The information processing device 100 acquires the processing request, for example, by receiving the processing request from the client device 201.

The information processing device 100 classifies a plurality of calculation nodes into a plurality of groups based on a remainder obtained by dividing a value indicating an access destination by the number of sets in a cache, according to the processing request. The information processing device 100 acquires profile information of the cache for at least any one of the plurality of groups. The information processing device 100 transmits the profile information acquired for the group to the client device 201, in association with any one group. The information processing device 100 is, for example, a server, a PC, or the like.

The client device 201 is a computer used by a service user. The client device 201 generates the processing request based on an operation input of the service user and transmits the processing request to the information processing device 100. The client device 201 receives the profile information associated with the group, from the information processing device 100. The client device 201 outputs the profile information associated with the group, so as to be referred from the service user. The client device 201 is, for example, a PC, a tablet terminal, a smartphone, or the like.

Here, a case has been described where the information processing device 100 acquires the processing request by receiving the processing request from the client device 201. However, the embodiment is not limited to this. For example, the information processing device 100 may acquire the processing request by receiving an input of the processing request based on the operation input of the service administrator.

Here, a case where the information processing device 100 and the client device 201 are different devices has been described. However, the embodiment is not limited to this. For example, the information processing device 100 may have a function as the client device 201, and may also be operable as the client device 201.

(Hardware Configuration Example of Information Processing Device 100)

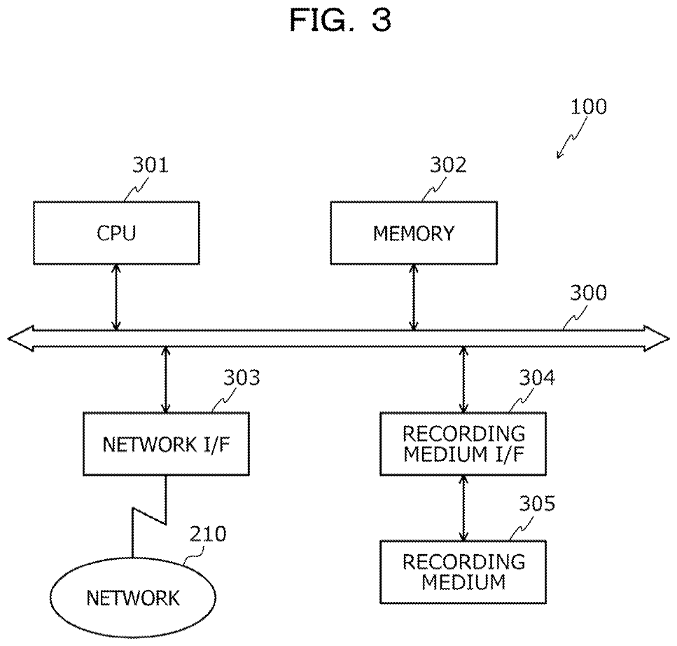

Next, a hardware configuration example of the information processing device 100 will be described with reference to FIG. 3.

FIG. 3 is a block diagram illustrating the hardware configuration example of the information processing device 100. In FIG. 3, the information processing device 100 includes a CPU 301, a memory 302, a network interface (I/F) 303, a recording medium I/F 304, and a recording medium 305. Furthermore, the components are coupled to each other with a bus 300.

Here, the CPU 301 performs overall control of the information processing device 100. The memory 302 includes, for example, a read only memory (ROM), a random access memory (RAM), a flash ROM, or the like. For example, the flash ROM or the ROM stores various programs, and the RAM is used as a work area for the CPU 301. The programs stored in the memory 302 are loaded into the CPU 301 to cause the CPU 301 to execute coded processing.

The network I/F 303 is coupled to the network 210 through a communication line and is coupled to another computer via the network 210. Then, the network I/F 303 controls an interface between the network 210 and the inside, and controls input/output of data to/from the another computer. The network I/F 303 is, for example, a modem, a LAN adapter, or the like.

The recording medium I/F 304 controls read/write of data from/to the recording medium 305 under the control of the CPU 301. The recording medium I/F 304 is, for example, a disk drive, a solid state drive (SSD), a universal serial bus (USB) port, or the like. The recording medium 305 is a nonvolatile memory that stores data written under the control of the recording medium I/F 304. The recording medium 305 is, for example, a disk, a semiconductor memory, a USB memory, or the like. The recording medium 305 may be attachable to and detachable from the information processing device 100.

The information processing device 100 may include, for example, a keyboard, a mouse, a display, a printer, a scanner, a microphone, a speaker, or the like in addition to the components described above. Furthermore, the information processing device 100 may include a plurality of the recording medium I/Fs 304 and recording media 305. Furthermore, the information processing device 100 does not have to include the recording medium I/F 304 or the recording medium 305.

(Functional Configuration Example of Information Processing Device 100)

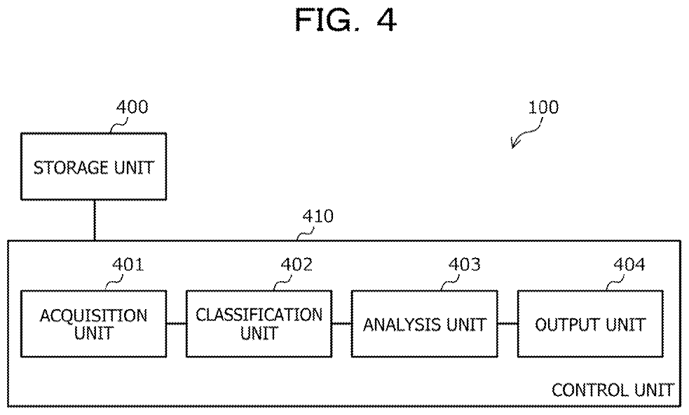

Next, a functional configuration example of the information processing device 100 will be described with reference to FIG. 4.

FIG. 4 is a block diagram illustrating the functional configuration example of the information processing device 100. The information processing device 100 includes a storage unit 400, an acquisition unit 401, a classification unit 402, an analysis unit 403, and an output unit 404.

The storage unit 400 is implemented by, for example, a storage area such as the memory 302 or the recording medium 305 illustrated in FIG. 3. Hereinafter, a case where the storage unit 400 is included in the information processing device 100 will be described. However, the embodiment is not limited to this. For example, the storage unit 400 may be included in a device different from the information processing device 100, and stored content of the storage unit 400 may be able to be referred from the information processing device 100.

The acquisition unit 401 to the output unit 404 function as an example of a control unit 410. For example, the acquisition unit 401 to the output unit 404 implement functions thereof by causing the CPU 301 to execute a program stored in the storage area such as the memory 302 or the recording medium 305 illustrated in FIG. 3 or by the network I/F 303. A processing result of each functional unit is stored in, for example, the storage area such as the memory 302 or the recording medium 305 illustrated in FIG. 3.

The storage unit 400 stores various types of information to be referred to or updated in processing of each functional unit. The storage unit 400 stores the number of calculation nodes that distribute an overall operation. The overall operation is formed of a plurality of calculations respectively having different content, for example. The overall operation is formed of arithmetic processing performed by the plurality of calculation nodes, for example. The overall operation corresponds to, for example, a large-scale HPC application.

The calculation node is, for example, a core. The calculation node is in charge of arithmetic processing regarding an access destination according to an identifier of the own node using a cache, for example. The access destination exists, for example, in a memory included in the calculation node. For example, the calculation node executes the arithmetic processing regarding the access destination according to the identifier of the own node, using the set in the cache corresponding to the remainder obtained by dividing the value indicating the access destination according to the identifier of the own node by the number of sets in the cache. The access destination is, for example, expressed by an address. The value corresponding to the access destination is, for example, a value obtained by dividing the address expressing the access destination by a size of a block. The number of calculation nodes is, for example, acquired by the acquisition unit 401.

The storage unit 400 stores the number of sets in a cache used for the overall operation. The storage unit 400 stores, for example, the number of sets in the cache that is included in the calculation node in charge of the overall operation and used when the calculation node executes the arithmetic processing in charge. The number of sets in the cache is, for example, acquired by the acquisition unit 401.

The storage unit 400 stores content of an overall operation. The storage unit 400 stores, for example, a program that defines the content of the overall operation. For example, the storage unit 400 stores a first program that enables to execute arithmetic processing in charge of each calculation node. The first program indicates, for example, arithmetic processing regarding an access destination according to an identifier of each calculation node, in a specifiable manner. The program is acquired by the acquisition unit 401, for example.

The acquisition unit 401 acquires various types of information to be used for processing of each functional unit. The acquisition unit 401 stores the various types of acquired information in the storage unit 400, or outputs the acquired information to each functional unit. Furthermore, the acquisition unit 401 may output the various types of information stored in the storage unit 400 to each functional unit. The acquisition unit 401 acquires the various types of information, for example, based on an operation input of a user. The acquisition unit 401 may receive the various types of information from, for example, a device different from the information processing device 100.

The acquisition unit 401 acquires a processing request. The processing request may indicate, for example, the number of calculation nodes that distribute the overall operation. The processing request may indicate, for example, the number of sets in a cache used for the overall operation. The processing request may indicate, for example, content of the overall operation. For example, the processing request may include the first program that enables to execute arithmetic processing in charge of each calculation node.

The acquisition unit 401 acquires the processing request, by receiving an input of the processing request, for example, based on an operation input of a user. The acquisition unit 401 acquires the processing request, for example, by receiving the processing request from another computer. The another computer is, for example, the client device 201.

The acquisition unit 401 may receive a start trigger to start processing of any one of the functional units. The start trigger is, for example, a predetermined operation input by a user. The start trigger may be, for example, reception of predetermined information from another computer. The start trigger may be, for example, output of predetermined information by any functional unit. The acquisition unit 401 receives, for example, acquisition of the processing request as a start trigger to start processing of the classification unit 402 and the analysis unit 403.

The classification unit 402 classifies a plurality of calculation nodes into a plurality of groups. For example, the classification unit 402 classifies the plurality of calculation nodes into the plurality of groups, based on the remainder obtained by dividing the value corresponding to the access destination by the number of sets in the cache. For example, the classification unit 402 classifies the plurality of calculation nodes into the plurality of groups, so that two or more different calculation nodes having the same remainder value are classified into the same group. As a result, the classification unit 402 can group the plurality of calculation nodes so as to group the calculation nodes having the same or similar access trends to the cache, based on the remainder.

The analysis unit 403 acquires profile information of a cache, corresponding to at least any one of the plurality of groups. For example, the analysis unit 403 selects a group to be processed, from among the plurality of groups. For example, the analysis unit 403 selects any one of the plurality of groups as a processing target. For example, the analysis unit 403 may select two or more groups as the processing targets. The analysis unit 403 may select all of the plurality of groups as the processing targets.

For example, the analysis unit 403 performs a simulation for imitating an access to the cache in the arithmetic processing, for at least any one calculation node classified into any one group, for any one of the selected groups. For example, the analysis unit 403 rewrites the first program corresponding to at least any one of the calculation nodes classified into any one of the selected groups as a second program that enables to perform the simulation. For example, the analysis unit 403 performs the simulation by executing the rewritten second program, for any one of the selected groups.

For example, as a result of performing the simulation, the analysis unit 403 acquires the profile information of the cache corresponding to any one of the selected groups. As a result, the analysis unit 403 can efficiently acquire the profile information of the cache. For example, the analysis unit 403 does not need to perform the simulation for all the calculation nodes classified into any one of the selected groups, and can reduce the processing load.

The analysis unit 403 performs the simulation for imitating the access to the cache in the arithmetic processing, for at least any one of the calculation nodes classified into the group, for each of the two or more selected groups. For example, the analysis unit 403 rewrites the first program corresponding to at least any one of the calculation nodes classified into each of the selected groups as the second program that enables to perform the simulation. For example, the analysis unit 403 performs the simulation, by executing the rewritten second program for each of the selected groups.

For example, as a result of performing the simulation, the analysis unit 403 acquires the profile information of the cache corresponding to each of the selected groups. As a result, the analysis unit 403 can efficiently acquire the profile information of the cache. For example, the analysis unit 403 does not need to perform the simulation for all the calculation nodes classified into the group, for each of the selected groups and can reduce the processing load.

For example, the analysis unit 403 may specify a first group of which an access trend to a cache satisfies a predetermined condition, from among two or more selected groups, based on the acquired profile information. The predetermined condition indicates, for example, that a cache miss ratio is equal to or more than a threshold. The predetermined condition may indicate, for example, a cache miss ratio of a group is relatively large, among the two or more selected groups.

For example, the analysis unit 403 may further select a second group that has a predetermined relation with the specified first group from among the plurality of groups, as a processing target. The second group is, for example, a group different from the first group. The predetermined relation indicates, for example, correspondence with another remainder having a value that is relatively close to a remainder corresponding to the first group.

For example, the analysis unit 403 performs the simulation for imitating the access to the cache in the arithmetic processing, for at least any one of the calculation nodes classified into the selected second group. For example, the analysis unit 403 rewrites the first program corresponding to at least any one of the calculation nodes classified into the selected second group as the second program that enables to perform the simulation. For example, the analysis unit 403 performs the simulation, by executing the rewritten second program for the selected second group.

For example, as a result of performing the simulation, the analysis unit 403 acquires profile information of a cache corresponding to the selected second group. As a result, the analysis unit 403 can efficiently acquire the profile information of the cache. For example, the analysis unit 403 does not need to perform the simulation for all the calculation nodes classified into the selected second group, and can reduce the processing load.

Furthermore, the analysis unit 403 can acquire the profile information of the cache corresponding to the second group that has the predetermined relation with the first group, so as to easily find a group that has a relatively large cache miss ratio, with reference to the first group. Therefore, the analysis unit 403 can easily find the group that has the relatively large cache miss ratio. The analysis unit 403 does not need to acquire the profile information of the cache for all of the plurality of groups and can reduce the processing load.

The analysis unit 403 performs the simulation for imitating the access to the cache in the arithmetic processing, for at least any one of the calculation nodes classified into the group, for each of the plurality of selected groups. For example, the analysis unit 403 rewrites the first program corresponding to at least any one of the calculation nodes classified into each of the selected groups as the second program that enables to perform the simulation. For example, the analysis unit 403 performs the simulation, by executing the rewritten second program for each of the selected groups.

For example, as a result of performing the simulation, the analysis unit 403 acquires the profile information of the cache corresponding to each of the selected groups. As a result, the analysis unit 403 can efficiently acquire the profile information of the cache. For example, the analysis unit 403 does not need to perform the simulation for all the calculation nodes classified into the group, for each of the selected groups and can reduce the processing load.

The analysis unit 403 may analyze the acquired profile information of the cache. For example, the analysis unit 403 specifies an access trend to the cache in the calculation node included in the selected group, based on the acquired profile information of the cache. For example, the analysis unit 403 specifies the group that has the relatively large cache miss ratio, from among the plurality of groups. As a result, the analysis unit 403 can reduce a work load of an analyst who analyzes the profile information.

The output unit 404 outputs a processing result of at least any one of the functional units. An output format is, for example, display on a display, print output to a printer, transmission to an external device by the network I/F 303, or storage in the storage area such as the memory 302 or the recording medium 305. As a result, the output unit 404 may make it possible for a user to be notified of the processing result of at least any one of the functional units, and may achieve improvement in convenience of the information processing device 100.

The output unit 404 outputs the acquired profile information for the selected group, in association with the group. The output unit 404 outputs, for example, the profile information so that the user can refer to the profile information. The output unit 404 transmits, for example, the profile information to another computer. The another computer is, for example, the client device 201. As a result, the output unit 404 enables to externally analyze the profile information.

The output unit 404 outputs the result of analyzing the profile information for the selected group, in association with the group. The output unit 404 outputs, for example, the result of analyzing the profile information so that the user can refer to the profile information. The output unit 404 transmits, for example, the result of analyzing the profile information to another computer. The another computer is, for example, the client device 201. As a result, the output unit 404 enables to externally refer to the result of analyzing the profile information.

(Operation Example of Information Processing Device 100)

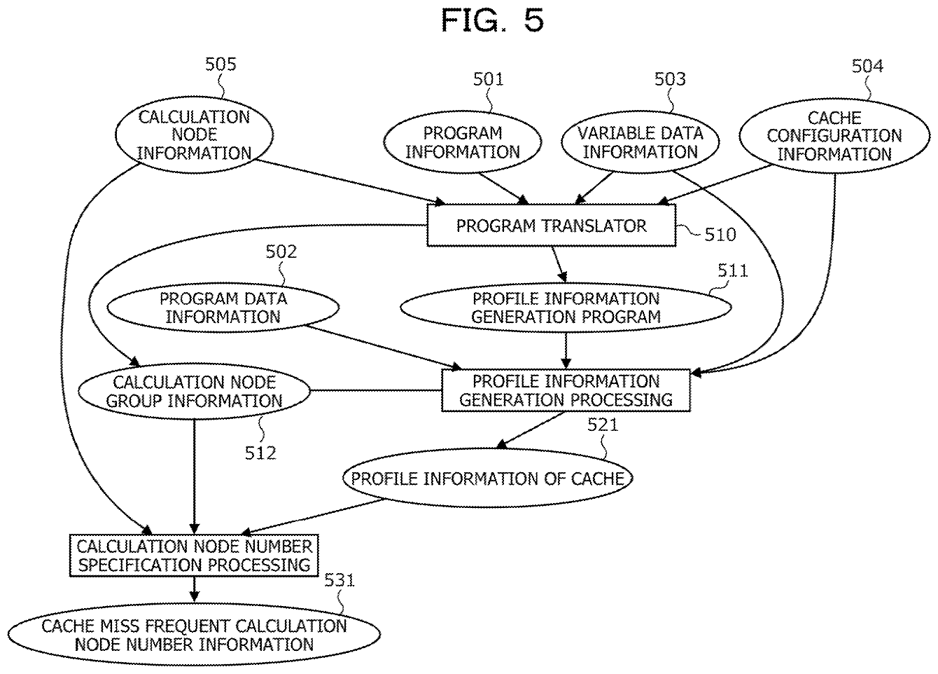

Next, an operation example of the information processing device 100 will be described with reference to FIGS. 5 to 14.

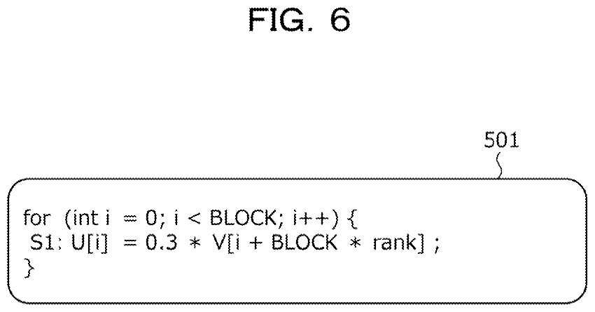

FIG. 5 is an explanatory diagram illustrating the operation example of the information processing device 100. In FIG. 5, the information processing device 100 receives inputs of program information 501, program data information 502, variable data information 503, cache configuration information 504, and calculation node information 505. Here, an example of content of the program information 501 will be described with reference to FIG. 6.

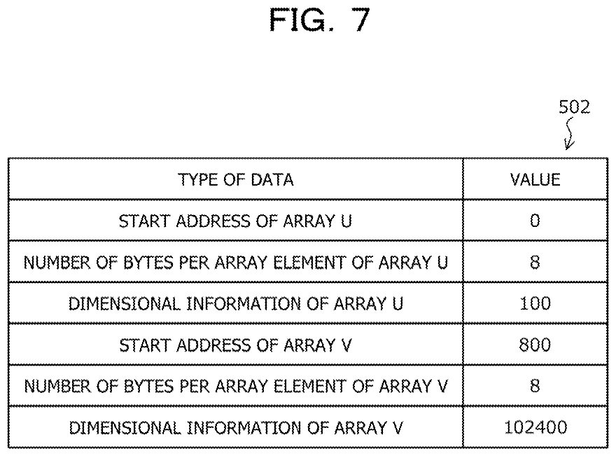

FIG. 6 is an explanatory diagram illustrating an example of the content of the program information 501. As illustrated in FIG. 6, the program information 501 defines a calculation using an array including a variable rank to be an assignment destination of a number of a calculation node. In a case where the program information 501 is executed in common with different calculation nodes, different calculations can be performed with different calculation nodes with the variable rank. Next, an example of content of the program data information 502 will be described with reference to FIG. 7.

FIG. 7 is an explanatory diagram illustrating an example of the content of the program data information 502. As illustrated in FIG. 7, the program data information 502 includes a parameter used when the program information 501 is executed.

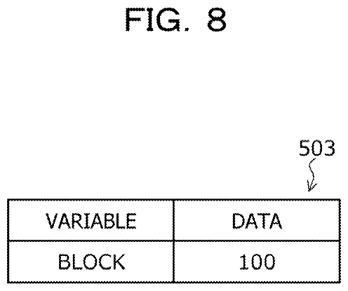

The program data information 502 includes, for example, a value of a start address of an array U. The program data information 502 includes, for example, a value of the number of bytes per array element of the array U. The program data information 502 includes, for example, a value of dimension information of the array U. The program data information 502 includes, for example, a value of a start address of an array V. The program data information 502 includes, for example, a value of the number of bytes per array element of the array V. The program data information 502 includes, for example, a value of dimension information of the array V. Next, an example of content of the variable data information 503 will be described with reference to FIG. 8.

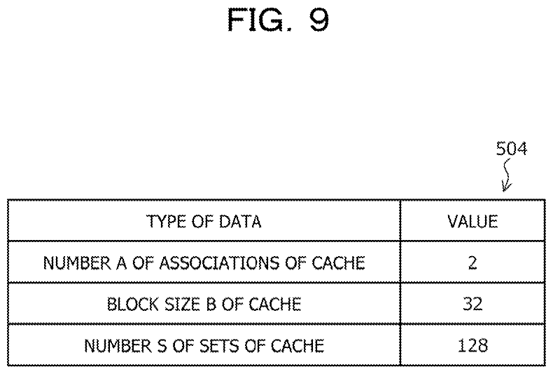

FIG. 8 is an explanatory diagram illustrating an example of the content of the variable data information 503. As illustrated in FIG. 8, the variable data information 503 includes a parameter used when the program information 501 is executed. The variable data information 503 includes, for example, data of a variable BLOCK. Next, an example of content of the cache configuration information 504 will be described with reference to FIG. 9.

FIG. 9 is an explanatory diagram illustrating an example of the content of the cache configuration information 504. As illustrated in FIG. 9, the cache configuration information 504 includes a parameter of a cache used when the program information 501 is executed.

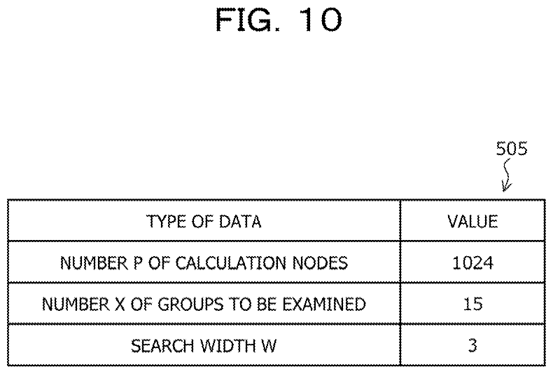

The cache configuration information 504 includes, for example, the number of associations A of the cache. The cache configuration information 504 includes, for example, a block size B of the cache. The cache configuration information 504 includes, for example, the number S of sets of the cache. Next, an example of content of the calculation node information 505 will be described with reference to FIG. 10.

FIG. 10 is an explanatory diagram illustrating an example of the content of the calculation node information 505. As illustrated in FIG. 10, the calculation node information 505 includes a parameter that defines how to acquire profile information 521, regarding a calculation node that executes the program information 501.

The calculation node information 505 includes, for example, the number P of calculation nodes. The calculation node information 505 includes, for example, the number X of groups to be examined. The number X of groups to be examined indicates the number of groups to be examined that acquire the profile information 521 first. The calculation node information 505 includes, for example, a search width W. The search width W is information that enables to specify a group to be examined that additionally acquires the profile information 521.

Here, returning to the description of FIG. 5, the information processing device 100 includes a program translator 510. The program translator 510 includes functions for generating a profile information generation program 511 and calculation node group information 512.

The profile information generation program 511 has a function that enables to generate the profile information 521 of the cache regarding the calculation node, by executing the profile information generation program 511 by the information processing device 100. For example, the profile information generation program 511 has a function for imitating an access to the cache when the calculation node executes the program information 501 and enables to generate the profile information 521 of the cache regarding the calculation node. For example, the profile information generation program 511 enables to generate the profile information 521 of the cache based on address information accessed by an array or command data in the program information 501 in a case where the calculation node executes the program information 501.

The calculation node group information 512 indicates a result of classifying different calculation nodes having the same access trend to the cache into the same group. The calculation node group information 512 indicates, for example, a group obtained by grouping the plurality of calculation nodes having the common profile information 521 of the cache. The group is expressed, for example, by a set of calculation node numbers of calculation nodes. When acquiring the profile information 521 of the cache regarding any one of the plurality of calculation nodes belonging to the same group, the information processing device 100 does not need to acquire the profile information 521 of the cache regarding other calculation nodes.

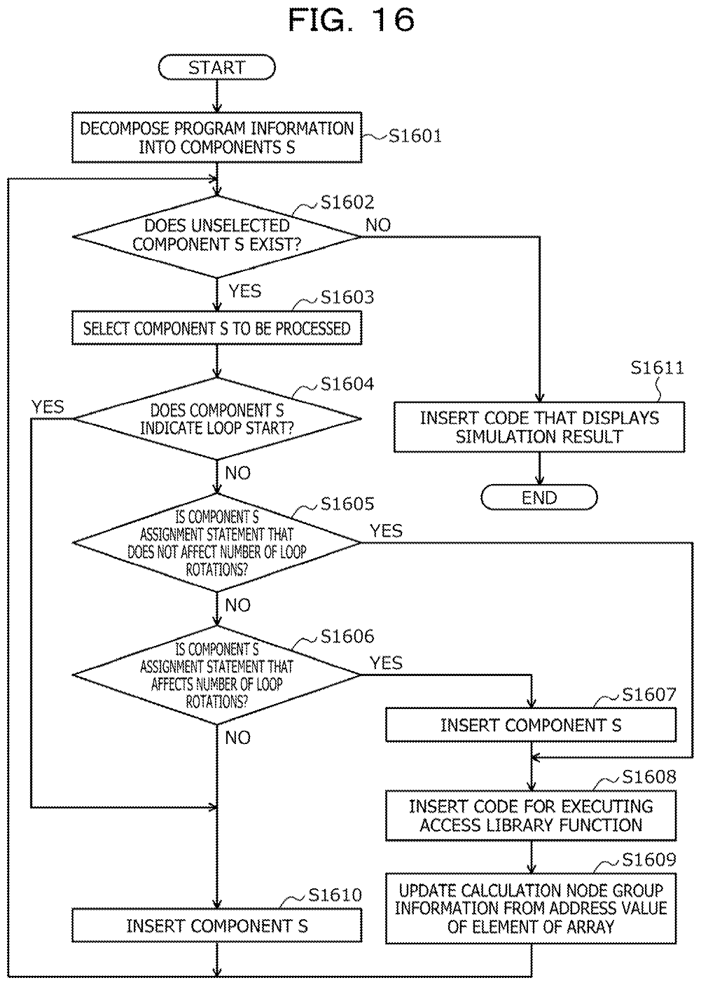

The information processing device 100 generates the profile information generation program 511 and the calculation node group information 512 using the program translator 510. For example, the information processing device 100 generates the profile information generation program 511 and the calculation node group information 512, by inputting the program information 501, the cache configuration information 504, and the calculation node information 505 into the program translator 510. For example, an example of a generation processing procedure for generating the profile information generation program 511 and the calculation node group information 512 by the program translator 510 will be described later with reference to FIG. 16.

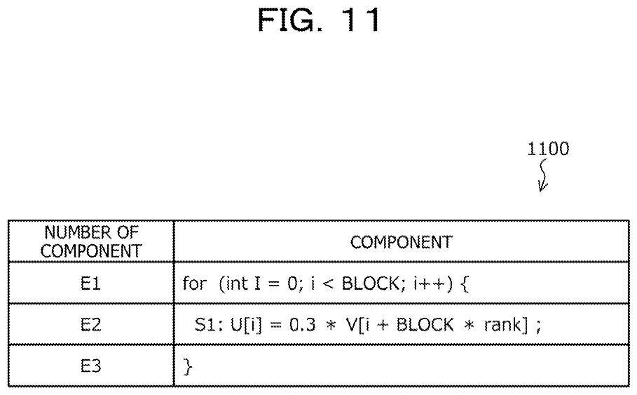

The program translator 510 receives, for example, inputs of the program information 501, the cache configuration information 504, and the calculation node information 505. The program translator 510 specifies, for example, each component S of the input program information 501. The component is, for example, all or a part of a statement, or the like. Here, an example of the component will be described with reference to FIG. 11.

FIG. 11 is an explanatory diagram illustrating an example of the component. A table 1100 in FIG. 11 indicates components. The table 1100 indicates, for example, a component to which a number E1 is added, a component to which a number E2 is added, and a component to which a number E3 is added. The component to which the number E1 is added indicates start of a loop. The component to which the number E2 is added indicates content of the loop. The component to which the number E3 is added indicates end of the loop.

Next, returning to the description of FIG. 5, the program translator 510 initializes the profile information generation program 511, for example. The program translator 510 initializes the calculation node group information 512, for example. The program translator 510 selects, for example, the component S as a processing target, in order from the beginning of the program information 501.

First, for example, the program translator 510 selects the component E1. For example, since the selected component E1 indicates the start of the loop, the program translator 510 inserts the selected component E1 into the profile information generation program 511 as it is.

Next, for example, the program translator 510 selects the component E2. For example, since the selected component E2 is an assignment statement that does not affect the number of loop rotations, the program translator 510 deletes the selected component E2 without inserting the component E2 into the profile information generation program 511.

Here, for example, the selected component E2 refers to elements of two arrays including V [i+BLOCK*rank] on the right side and U [i] on the left side. Therefore, for example, the program translator 510 inserts a statement that executes an ACCESS library function for acquiring the profile information 521 of the cache on each array element, into the profile information generation program 511.

For example, the program translator 510 inserts ACCESS (address (V [i+BLOCK*rank])); and ACCESS (address (U [i])); into the profile information generation program 511. The function address (D) has, for example, a function for acquiring an address value of data D of the array element. The function address (D) is implemented by using an operator & on a C language program, for example.

A library function ACCESS (A) has, for example, a function for receiving an address value of an accessed array element, as an argument A. The library function ACCESS (A) has, for example, a function for simulating an access to an address specified by the argument A, for a cache of cache configuration information of input data.

Moreover, an array reference V [i+BLOCK*rank] on the right side in the selected component E2 includes a rank variable rank representing a number of a calculation node. Therefore, for example, the program translator 510 updates the calculation node group information 512.

For example, the program translator 510 acquires a value of the start address of the array V=800 and a value of the number of bytes per array element=8, from the program data information 502. For example, the program translator 510 acquires a value of the variable BLOCK=100 from the variable data information 503.

For example, the program translator 510 acquires the block size B of the cache=32 and a value of the number S of sets of the cache=128, from the cache configuration information 504. For example, the program translator 510 acquires a value of the number P of calculation nodes=1024, from the calculation node information 505.

Here, the array reference V [i+BLOCK*rank] includes the rank variable rank. The rank variable rank takes a value in a range of zero to 1023, according to the number of the calculation node. Furthermore, in the array reference V [i+BLOCK*rank], a set number of a cache to be accessed by the calculation node takes a value in a range of zero to 127.

A set number s of the cache to be accessed by the calculation node is specified by s=(a/B) mod (S), based on an address value a of the array reference V [i+BLOCK*rank]. In the example in FIG. 5, s=((800+8 (i+100*rank))/32) mod (128).

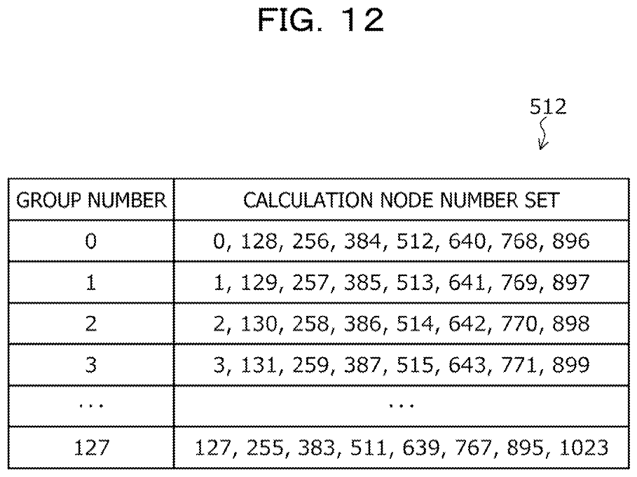

Therefore, a calculation node of which the value of the rank variable rank=0 and a calculation node of which the value of the rank variable rank=128 have properties such that the value of s corresponding to the value of each i becomes the same. For example, the program translator 510 classifies 1024 calculation nodes into 128 groups using the above property and updates the calculation node group information 512. Here, the description proceeds to FIG. 12, and an example of the calculation node group information 512 will be described.

FIG. 12 is an explanatory diagram illustrating an example of the calculation node group information 512. As illustrated in FIG. 12, the calculation node group information 512 indicates a group number and a calculation node number set in association with each other. The group number is, for example, a group number used to identify a group into which a calculation node is classified. The calculation node number set is, for example, a list of numbers added to the respective calculation nodes belonging to the group.

Here, a calculation node, to which each of a plurality of calculation node numbers associated with the same group number is added, has the same access trend to the cache and corresponds to the profile information 521 of the same cache. Therefore, when acquiring the profile information 521 of the cache for any one of the calculation nodes belonging to the same group, the information processing device 100 does not need to acquire the profile information 521 of the cache for the other calculation nodes belonging to the same group.

Next, returning to the description of FIG. 5, for example, the program translator 510 selects the component E3. For example, since the selected component E3 indicates the end of the loop, the program translator 510 inserts the selected component E3 into the profile information generation program 511.

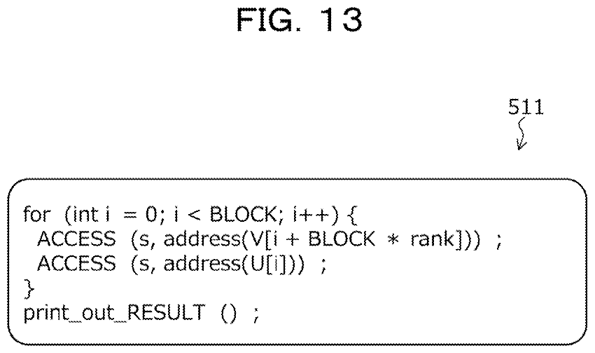

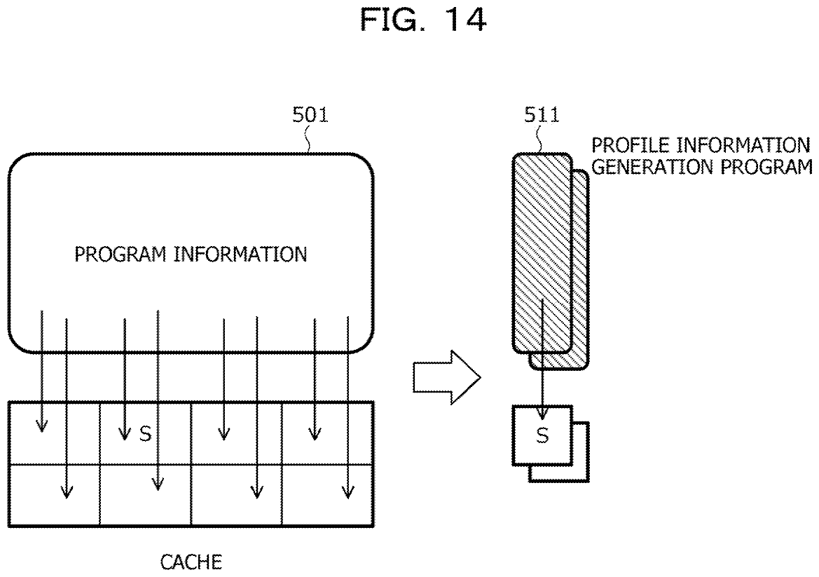

For example, the selection of the component S has been completed, the program translator 510 inserts a statement “print_out_RESULT( );” into the profile information generation program 511. The statement “print_out_RESULT( );” is a statement used to output the profile information 521 of the cache as an execution result. For example, a function print_out_RESULT( ) has a function for outputting the profile information 521 of the cache for performing a simulation with a library function ACCESS. The function print_out_RESULT( ) is implemented by executing DUMP on all the sets in the cache. Next, an example of the profile information generation program 511 will be described with reference to FIGS. 13 and 14.

FIGS. 13 and 14 are explanatory diagrams illustrating an example of the profile information generation program 511. As described above, the information processing device 100 can generate the profile information generation program 511 so as to have content illustrated in FIG. 13. Next, description proceeds to FIG. 14.

As illustrated in FIG. 14, the program information 501 uses each of a plurality of sets in a cache. On the other hand, the profile information generation program 511 is defined to use any one of sets in a cache according to a rank variable.

Therefore, by generating the profile information generation program 511 from the program information 501, the information processing device 100 does not need to prepare an actual machine of the calculation node. Furthermore, the information processing device 100 enables to acquire the profile information 521 for each set in the cache, except for a statement such as a memory access or calculation and can reduce the processing load. Furthermore, the information processing device 100 can obtain the profile information generation programs 511 that can be executed in parallel and can reduce the processing load.

Next, returning to the description of FIG. 5, the information processing device 100 executes the generated profile information generation program 511 using the program data information 502 and the variable data information 503 as inputs. By executing the generated profile information generation program 511, the information processing device 100 acquires the profile information 521 of the cache for each of X calculation nodes.

For example, the information processing device 100 sets the number of groups to be examined in the calculation node information 505 as a value X. For example, the information processing device 100 sets 15 as the value X. For example, the information processing device 100 selects the X calculation node groups, based on the calculation node group information 512. For example, the information processing device 100 selects a calculation node group for every eight calculation node groups, from among 128 calculation node groups, based on a result of dividing 128 by 15. For example, the information processing device 100 selects 15 calculation node groups having calculation node group numbers {G0, G8, G16, G24, G32, G40, G48, G56, G64, G72, G80, G88, G96, G104, G112}.

For example, the information processing device 100 acquires the profile information 521 of the cache for any one of the calculation nodes included in the calculation node group, for each of the selected calculation node group. For example, the information processing device 100 acquires the profile information 521 of the cache for a calculation node with the smallest calculation node number included in the calculation node group, for each calculation node group. For example, the information processing device 100 acquires the profile information 521 of the cache for calculation nodes with calculation node numbers {0, 8, 16, 24, 32, 40, 48, 56, 64, 72, 80, 88, 96, 104, 112}. When acquiring the profile information 521 of the cache, the information processing device 100 uses the library functions ACCESS and DUMP, based on the cache configuration information 504.

The information processing device 100 specifies a calculation node number added to a calculation node having the largest number of cache misses, based on the acquired profile information 521. For example, the information processing device 100 specifies calculation node numbers {56, 104} added to the calculation nodes having the largest number of cache misses. In this case, the numbers of cache misses of all the calculation nodes belonging to the calculation node groups having the calculation node group numbers {G56, G104}, among the plurality of calculation node groups, are relatively large.

The information processing device 100 acquires the profile information 521 of the cache, for any one of the calculation nodes included in the calculation node group having the calculation node group number that exists in a range including W numbers before and after the calculation node group number including the specified calculation node numbers. For example, the information processing device 100 sets three as the value W, based on the calculation node information 505. For example, the information processing device 100 selects a calculation node group number that exists in a range including three numbers before and after the calculation node group number including the specified calculation node numbers. For example, the information processing device 100 selects calculation node group numbers {G53, G54, G55, G57, G58, G59, G101, G102, G103, G105, G106, G107}.

For example, the information processing device 100 acquires the profile information 521 of the cache, for any one of the calculation nodes included in the calculation node groups having the selected calculation node group numbers. For example, the information processing device 100 acquires the profile information 521 of the cache, for a calculation node having the smallest calculation node number included in the calculation node group, for each calculation node group with the selected calculation node group number. For example, the information processing device 100 acquires the profile information 521 of the cache, for calculation nodes having calculation node numbers {53, 54, 55, 57, 58, 59, 101, 102, 103, 105, 106, 107}.

The information processing device 100 specifies a calculation node number added to a calculation node having the largest number of cache misses, based on the acquired profile information 521 of the cache and specifies a calculation node group corresponding to the specified calculation node number. The information processing device 100 generates cache miss frequent calculation node number information 531 including the calculation node number of the calculation node included in the specified calculation node group.

As a result, for example, the information processing device 100 can detect that the calculation node with the smallest calculation node number has the largest number of cache misses, in the calculation node group having the calculation node group number G101. Therefore, for example, the information processing device 100 can indirectly detect that the number of cache misses is the largest, for all the calculation nodes included in the calculation node group having the calculation node group number G101.

Therefore, the information processing device 100 can reduce the processing load caused when the calculation node having the largest number of cache misses is found. Typically, for example, a time required for acquiring the profile information of the cache by executing the program information 501 and finding the calculation node having the largest number of cache misses is several hours or several days. On the other hand, the information processing device 100 can reduce the time required when the calculation node having the largest number of cache misses is found. Even if the number of calculation nodes is enormous, the information processing device 100 can reduce the time required when the calculation node having the largest number of cache misses is found.

(Overall Processing Procedure)

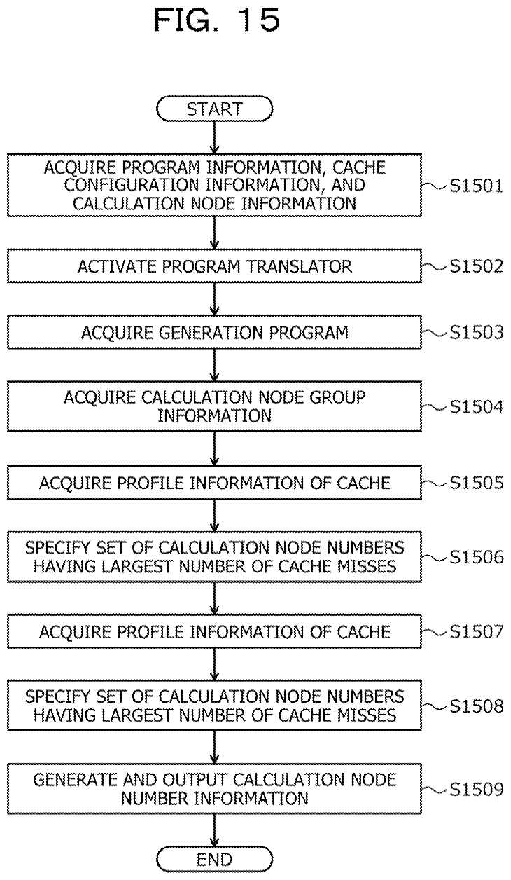

Next, an example of an overall processing procedure executed by the information processing device 100 will be described with reference to FIG. 15. Overall processing is implemented by, for example, the CPU 301, the storage area such as the memory 302 or the recording medium 305, and the network I/F 303 illustrated in FIG. 3.

FIG. 15 is a flowchart illustrating an example of the overall processing procedure. The information processing device 100 acquires program information, cache configuration information, and calculation node information (step S1501).

Next, the information processing device 100 activates a program translator using the program information, the cache configuration information, and the calculation node information as inputs and executes generation processing to be described later with reference to FIG. 16 (step S1502). Then, the information processing device 100 acquires a generation program for generating the profile information of the cache, from the activated program translator (step S1503). Furthermore, the information processing device 100 acquires calculation node group information representing a result of grouping a plurality of calculation nodes, from the activated program translator (step S1504).

Next, the information processing device 100 sets the number of groups to be examined in the calculation node information as X. The information processing device 100 performs a simulation for a calculation node included in each of X groups by executing the acquired generation program and acquires profile information of a cache corresponding to the group (step S1505). Then, the information processing device 100 specifies a set of calculation node numbers having the largest number of cache misses, based on the acquired profile information (step S1506).

Next, the information processing device 100 sets a search width in the calculation node information as W. The information processing device 100 acquires profile information of a cache for a calculation node having a calculation node number that exists in a range including W numbers before and after each calculation node number included in the specified set of the calculation node numbers (step S1507). Then, the information processing device 100 specifies the set of the calculation node numbers having the largest number of cache misses, based on the profile information acquired in steps S1505 and S1507 (step S1508).

Next, the information processing device 100 generates and outputs calculation node number information representing the set of the calculation node numbers specified in step S1508 (step S1509). Then, the information processing device 100 ends the overall processing. As a result, the information processing device 100 can efficiently specify the set of the calculation node numbers having the largest number of cache misses and enables a user to refer to the specified set.

(Generation Processing Procedure)

Next, an example of the generation processing procedure executed by the information processing device 100 will be described with reference to FIG. 16. The generation processing is implemented, for example, by the CPU 301, the storage area such as the memory 302 and the recording medium 305, and the network I/F 303 illustrated in FIG. 3.

FIG. 16 is a flowchart illustrating an example of the generation processing procedure. In FIG. 16, the information processing device 100 decomposes the input program information into components S (step S1601).

Next, the information processing device 100 determines whether or not a component S that is not selected as a processing target exists among the components S of the input program information (step S1602). Here, in a case where the component S that is not selected as the processing target does not exist (step S1602: No), the information processing device 100 proceeds to processing in step S1611. On the other hand, in a case where the component S that is not selected as the processing target exists (step S1602: Yes), the information processing device 100 proceeds to processing in step S1603.

In step S1603, the information processing device 100 selects the component S to be processed, from among the components S of the input program information (step S1603).

Next, the information processing device 100 determines whether or not the component S indicates loop start (step S1604). Here, in a case where the component S indicates the loop start (step S1604: Yes), the information processing device 100 proceeds to processing in step S1610. On the other hand, in a case where the component S does not indicate the loop start (step S1604: No), the information processing device 100 proceeds to processing in step S1605.

In step S1605, the information processing device 100 determines whether or not the component S is an assignment statement that does not affect the number of loop rotations (step S1605). Here, in a case where the component S is the assignment statement that does not affect the number of loop rotations (step S1605: Yes), the information processing device 100 deletes the component S and proceeds to processing in step S1608. On the other hand, in a case where the component S is not the assignment statement that does not affect the number of loop rotations (step S1605: No), the information processing device 100 proceeds to processing in step S1606.

In step S1606, the information processing device 100 determines whether or not the component S is an assignment statement that affects the number of loop rotations (step S1606). Here, in a case where the component S is the assignment statement that affects the number of loop rotations (step S1606: Yes), the procedure proceeds to processing in step S1607. On the other hand, in a case where the component S is not the assignment statement that affects the number of loop rotations (step S1606: No), the information processing device 100 determines that the component S indicates loop end and proceeds to processing in step S1610.

In step S1607, the information processing device 100 inserts the component S into the generation program (step S1607). Next, the information processing device 100 inserts a code for executing the ACCESS library function into the generation program, for each term t that refers to an element of an array that appears in the assignment statement that is the component S (step S1608).

Then, if the term t that refers to the element of the array includes a rank variable representing a calculation node number, the information processing device 100 updates the calculation node group information from an address value of the element of the array (step S1609). Thereafter, the information processing device 100 returns to the processing in step S1602.

In step S1610, the information processing device 100 inserts the component S into the generation program (step S1610). Then, the information processing device 100 returns to the processing in step S1602.

In step S1611, the information processing device 100 inserts a code that displays a simulation result into the generation program (step S1611). Then, the information processing device 100 ends the generation processing. As a result, the information processing device 100 can generate the generation program that can efficiently acquire the profile information of the cache.

Here, the information processing device 100 may transpose orders of the processing in some steps in each of the flowcharts in FIGS. 15 and 16 and execute the processing. For example, the orders of the processing in steps S1605 and S1606 can be transposed. Furthermore, the information processing device 100 may omit the processing in some steps in each of the flowcharts in FIGS. 15 and 16. For example, the processing in step S1509 can be omitted.

As described above, according to the information processing device 100, it is possible to classify the plurality of calculation nodes into the plurality of groups, based on the remainder obtained by dividing the value corresponding to the access destination by the number of sets in the cache. According to the information processing device 100, it is possible to perform the simulation for imitating the access to the cache in the arithmetic processing, for at least any one of the calculation nodes classified into any one group, for any one of the plurality of groups. According to the information processing device 100, it is possible to acquire the profile information of the cache, corresponding to any one group, by performing the simulation. As a result, the information processing device 100 can efficiently acquire the profile information of the cache.

According to the information processing device 100, it is possible to select two or more groups from among the plurality of groups. According to the information processing device 100, it is possible to perform the simulation for imitating the access to the cache in the arithmetic processing, for at least any one of the calculation nodes classified into the group, for each of the two or more selected groups. According to the information processing device 100, it is possible to acquire the profile information of the cache corresponding to the group, by performing the simulation. As a result, the information processing device 100 can easily determine profile information of a cache corresponding to which group is preferable to be acquired and can easily acquire useful profile information of the cache. The information processing device 100 can easily analyze the access trend of the cache of the calculation node.

According to the information processing device 100, it is possible to specify the first group of which the access trend to the cache satisfies the predetermined condition, from among the two or more selected groups, based on the acquired profile information. According to the information processing device 100, it is possible to select the second group that has the predetermined relation with the specified first group, from among the plurality of groups. According to the information processing device 100, it is possible to perform the simulation for imitating the access to the cache in the arithmetic processing, for at least any one of the calculation nodes classified into the second group. According to the information processing device 100, it is possible to acquire the profile information of the cache corresponding to the second group, by performing the simulation. As a result, the information processing device 100 can determine the profile information of the cache corresponding to which group is preferable to be acquired and select the second group. The information processing device 100 can easily acquire the useful profile information of the cache.

According to the information processing device 100, it is possible to perform the simulation for imitating the access to the cache in the arithmetic processing, for at least any one of the calculation nodes classified into the group, for each of the plurality of groups. According to the information processing device 100, it is possible to acquire the profile information of the cache corresponding to the group, by performing the simulation. As a result, the information processing device 100 can comprehensively and efficiently acquire the profile information of the cache.

According to the information processing device 100, it is possible to rewrite the first program that enables to execute the arithmetic processing corresponding to at least any one of the calculation nodes classified into any one group to the second program that enables to perform the simulation. According to the information processing device 100, it is possible to acquire the profile information of the cache corresponding to any one group, by executing the rewritten second program, for any one group. As a result, the information processing device 100 can easily acquire the profile information of the cache.

According to the information processing device 100, it is possible to output the acquired profile information for any one group in association with any one group. As a result, the information processing device 100 can make the user easily refer to the profile information.

Note that the information processing method described in the present embodiment may be implemented by executing a program prepared in advance on a computer such as a PC or a workstation. The information processing program described in the present embodiment is executed by being recorded on a computer-readable recording medium and being read from the recording medium by the computer.

The recording medium is a hard disk, a flexible disk, a compact disc read only memory (CD-ROM), a magneto optical disc (MO), a digital versatile disc (DVD), or the like. Furthermore, the information processing program described in the present embodiment may be distributed via a network such as the Internet.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A non-transitory computer-readable recording medium storing an information processing program for causing a computer to execute processing comprising:
classifying a plurality of calculation nodes each in charge of arithmetic processing regarding to an access destination according to an identifier of an own node by using a cache into a plurality of groups, based on a remainder obtained by dividing a value that corresponds to the access destination by the number of sets in the cache; and
acquiring profile information of the cache, that corresponds to any one group, by performing a simulation that imitates an access to the cache in the arithmetic processing, for at least any one of the calculation nodes classified into any one group, for any one of the plurality of groups.

2. The non-transitory computer-readable recording medium according to claim 1, for causing the computer to execute processing comprising:
selecting two or more groups from among the plurality of groups, wherein
the acquiring processing
acquires the profile information of the cache, that corresponds to the group, by performing the simulation that imitates the access to the cache in the arithmetic processing, for at least any one of the calculation nodes classified into the group, for each of the two or more selected groups.

3. The non-transitory computer-readable recording medium according to claim 2, for causing the computer to execute processing comprising:
specifying a first group of which an access trend to the cache satisfies a predetermined condition, from among the two or more selected groups, based on the acquired profile information; and
acquiring profile information of the cache, that corresponds to a second group, by performing the simulation that imitates the access to the cache in the arithmetic processing, for at least any one of calculation nodes classified into the second group that has a predetermined relation with the specified first group, from among the plurality of groups.

4. The non-transitory computer-readable recording medium according to claim 1, wherein
the acquiring processing
acquires the profile information of the cache, that corresponds to the group, by performing the simulation that imitates the access to the cache in the arithmetic processing, for at least any one of calculation nodes classified into the group, for each of the plurality of groups.

5. The non-transitory computer-readable recording medium according to claim 4, for causing the computer to execute processing comprising:
rewriting a first program that enables to execute the arithmetic processing, that corresponds to at least any one of the calculation nodes classified into any one of the groups into a second program that enables to perform the simulation, for any one group, wherein
the acquiring processing
acquires the profile information of the cache, that corresponds to any one group, by executing the rewritten second program for any one group.

6. The non-transitory computer-readable recording medium according to claim 1, for causing the computer to execute processing comprising:
outputting the acquired profile information for any one group, in association with any one group.

7. An information processing method comprising:
classifying a plurality of calculation nodes each in charge of arithmetic processing regarding to an access destination according to an identifier of an own node by using a cache into a plurality of groups, based on a remainder obtained by dividing a value that corresponds to the access destination by the number of sets in the cache; and
acquiring profile information of the cache, that corresponds to any one group, by performing a simulation that imitates an access to the cache in the arithmetic processing, for at least any one of the calculation nodes classified into any one group, for any one of the plurality of groups.

8. An information processing device comprising:
a memory; and
a processor coupled to the memory and configured to:
classify a plurality of calculation nodes each in charge of arithmetic processing regarding to an access destination according to an identifier of an own node by using a cache into a plurality of groups, based on a remainder obtained by dividing a value that corresponds to the access destination by the number of sets in the cache; and
acquire profile information of the cache, that corresponds to any one group, by performing a simulation that imitates an access to the cache in the arithmetic processing, for at least any one of the calculation nodes classified into any one group, for any one of the plurality of groups.
